(19) United States
(12) Patent Application Publication
(10) Pub. No.: US 2025/0311207 A1
(43) Pub. Date: Oct. 2, 2025

(54) MEMORY DEVICES AND MANUFACTURING METHODS THEREOF

(71) Applicant: YANGTZE MEMORY TECHNOLOGIES CO., LTD., Wuhan (CN)

(72) Inventor: Jinlong FENG, Wuhan (CN)

(21) Appl. No.: 18/965,710

(22) Filed: Dec. 2, 2024

(30) Foreign Application Priority Data
Apr. 1, 2024 (CN) 202410390080.X

(51) Int. Cl. H10B 12/00

(52) U.S. Cl. CPC H10B 12/50; H10B 12/09; H10B 12/315; H10B 12/482; H10B 12/485

(57) ABSTRACT

The present disclosure provides a memory device and a manufacturing method thereof. The memory device includes a first semiconductor structure that includes a first region. The first region includes: a conductive line including two first portions extending along a first direction and a second portion connecting the two first portions, wherein the second portion is connected to one of two opposite ends of the first portion along the first direction; and a contact structure extending along a second direction, wherein one of two opposite ends of the contact structure along the second direction is connected to the second portion; and the second direction is perpendicular to the first direction.

### CROSS-REFERENCE TO RELATED APPLICATIONS

The present application claims the benefit of priority to Chinese Application No. 202410390080.X, filed on Apr. 1, 2024, which is hereby incorporated by reference in its entirety.

### TECHNICAL FIELD

The present disclosure relates to the field of semiconductor technology, and particularly to memory devices and a manufacturing methods thereof.

### BACKGROUND

A vertical channel transistor occupies a smaller area than a planar transistor, and thus can be used for improving an integration level of a memory device.

### SUMMARY

According to one aspect of the present disclosure, a memory device is provided, the memory device may include a first semiconductor structure. The first semiconductor structure may include a first region. The first region may include a conductive line. The conductive line may include two first portions extending along a first direction. The conductive line may further include a second portion. The second portion may be connected to the two first portions. The second portion may be connected to one of two opposite ends of the first portion along the first direction. The first region may further include a contact structure extending along a second direction. One of two opposite ends of the contact structure along the second direction may be connected to the second portion. The second direction is perpendicular to the first direction.

In an implementation. The first region may further includes a plurality of resistor structures extending along the second direction. One of two opposite ends of at least one of the resistor structures along the second direction may be connected to the first portion.

In an implementation, the resistor structures may include a doped semiconductor material.

In an implementation, a doping concentration of the doped semiconductor material may be greater than 1×10¹⁵ cm⁻³.

In an implementation, the doped semiconductor material may include an N-type material or a P-type material.

In an implementation, a number of the resistor structures connected to one of the two first portions of the conductive line is equal to a number of the resistor structures connected to the other one of the two first portions of the conductive line.

In an implementation, the first region may further include a plurality of first capacitor structures extending along the second direction. The other one of the two opposite ends of one of the resistor structures along the second direction may be connected to one of the first capacitor structures.

In an implementation, the two first portions of the conductive line may have a same size in the first direction.

In an implementation, the conductive line may include a metal silicide.

In an implementation, the memory device may further include a second semiconductor structure. The first semiconductor structure and the second semiconductor structure may be stacked along the second direction. The first semiconductor structure may include the first region and a second region that are arranged in juxtaposition along a direction perpendicular to the second direction. The second region may include a plurality of memory cells arranged in an array. The second semiconductor structure may include a peripheral circuit. The other one of the two opposite ends of the contact structure along the second direction may be connected to the peripheral circuit.

In an implementation, the second region may further include a bit line structure extending along the first direction. The second region may further include a bit line lead-out structure extending along the second direction. One of two opposite ends of the bit line lead-out structure along the second direction may be connected to one of two opposite ends of the bit line structure along the first direction.

In an implementation, the memory cell may include an active pillar and a second capacitor structure. The active pillar and the second capacitor structure may both extend along the second direction. The active pillar may include a first electrode structure. The active pillar may further include a channel structure and a second electrode structure that are arranged along the second direction. One of the first electrode structure and the second electrode structure may be connected to the bit line structure, and the other one of the first electrode structure and the second electrode structure may be connected to the second capacitor structure.

In an implementation, the second region may be symmetrically distributed on two sides of the first region along the first direction. In an implementation, the second region may be symmetrically distributed on two sides of the first region along a third direction that is perpendicular to both the first direction and the second direction. In an implementation, the first region may be symmetrically distributed on two sides of the second region along the first direction. In an implementation, the first region may be symmetrically distributed on two sides of the second region along the third direction.

According to another aspect of the present disclosure, a memory device is provided. The memory device may include a first semiconductor structure. The first semiconductor structure may include a first region. The first region may include at least one sub-region. At least one of sub-region may include a first conductive line group and a second conductive line group arranged along a first direction. The first conductive line group and the second conductive line group may include a plurality of conductive lines arranged along a third direction. The conductive line may include two first portions extending along the first direction and a second portion connecting the two first portions. The second portion may be connected to one of two opposite ends of the first portion along the first direction. The second portion of each of the conductive lines in the first conductive line group may be located on one of two sides of the first portion along the first direction away from the second conductive line group. The second portion of each of the conductive lines in the second conductive line group may be located on one of two sides of the first portion along the first direction away from the first conductive line group. The third direction is perpendicular to the first direction. The sub-region may further include a plurality of contact structures extending along a second direction. One of two opposite ends of one of the contact structures along the second direction may be connected to the second portion of one of the conductive lines. The second direction is perpendicular to the first direction.

In an implementation, the sub-region may further include a plurality of resistor structures extending along the second direction and arranged in an array along the first direction and the third direction. One of two opposite ends of each of the resistor structures along the second direction may be connected to the first portion.

In an implementation, the resistor structures may include a doped semiconductor material. In an implementation, the sub-region may further include a plurality of first capacitor structures extending along the second direction. The other one of the two opposite ends of one of the resistor structures along the second direction may be connected to one of the first capacitor structures.

In an implementation, the memory device may further include a second semiconductor structure. The first semiconductor structure and the second semiconductor structure may be stacked along the second direction. The first semiconductor structure may include the first region and a second region that are arranged in juxtaposition along a direction perpendicular to the second direction. The second region may include a plurality of memory cells arranged in an array. The second semiconductor structure may include a peripheral circuit. The other one of the two opposite ends of the contact structure along the second direction may be connected to the peripheral circuit.

In an implementation, in the sub-region, a size of the conductive lines in the first conductive line group in the first direction may be the same as a size of the conductive line in the second conductive line group in the first direction. A size of the conductive lines in the first conductive line group in the third direction may be the same as a size of the conductive line in the second conductive line group in the third direction.

In an implementation, the sub-region may further include an isolation structure located between the first conductive line group and the second conductive line group in the first direction and extending along the third direction. The conductive lines in the first conductive line group and the conductive lines in the second conductive line group may be symmetrically distributed on two sides of the isolation structure along the first direction.

In an implementation, the second region may further include a plurality of bit line structures extending along the first direction and arranged along the third direction. The second region may further include a plurality of bit line lead-out structures extending along the second direction. One of two opposite ends of one of the bit line lead-out structures along the second direction may be connected to one of two opposite ends of one of the bit line structures along the first direction.

According to a further aspect of the present disclosure, a manufacturing method of a memory device is provided. The method may include forming a conductive line in a first region of a first semiconductor structure. The conductive line may include two first portions extending along a first direction and a second portion connecting the two first portions, and the second portion may be connected to one of two opposite ends of the first portion along the first direction. The method may further include forming a contact structure in the first region. The contact structure may extend along a second direction, and one of two opposite ends of the contact structure along the second direction may be connected to the second portion. The second direction is perpendicular to the first direction.

In an implementation, the manufacturing method of the memory device may further include forming a plurality of resistor structures in the first region. The resistor structures may extend along the second direction, and one of two opposite ends of each of the resistor structures along the second direction may be connected to the first portion.

In an implementation, forming the plurality of resistor structures may include forming a plurality of semiconductor pillars extending along the second direction. Forming the plurality of resistor structures may further include doping the semiconductor pillars to form the plurality of resistor structures.

In an implementation, the manufacturing method of the memory device may further include forming a plurality of first capacitor structures in the first region. The first capacitor structures may extend along the second direction, and the other one of the two opposite ends of one of the resistor structures along the second direction may be connected to one of the first capacitor structures.

In an implementation, the manufacturing method of the memory device may further include forming a plurality of memory cells arranged in an array in a second region of the first semiconductor structure. The first region and the second region may be arranged in juxtaposition along a direction perpendicular to the second direction. The method may further include forming a peripheral circuit in a second semiconductor structure. The method may further include bonding the first semiconductor structure to the second semiconductor structure to form a bonding interface between the first semiconductor structure and the second semiconductor structure. The other one of the two opposite ends of the contact structure along the second direction may be connected to the peripheral circuit.

In an implementation, the manufacturing method of the memory device may further include forming a bit line structure extending along the first direction in the second region. The method may further include forming a bit line lead-out structure extending along the second direction in the second region. One of two opposite ends of the bit line lead-out structure along the second direction may be connected to one of two opposite ends of the bit line structure along the first direction.

In an implementation, forming the conductive line in the first region and forming the contact structure in the first region may include forming a first conductive line group and a second conductive line group arranged along the first direction in each sub-region of the first region. The first conductive line group and the second conductive line group may include a plurality of conductive lines arranged along a third direction. The second portion of the conductive lines in the first conductive line group may be located on one of two sides of the first portion along the first direction away from the second conductive line group. The second portion of each of the conductive lines in the second conductive line group may be located on one of two sides of the first portion along the first direction away from the first conductive line group. The third direction is perpendicular to the first direction. The method may further include forming a plurality of contact structures in each sub-region of the first region. One of two opposite ends of one of the contact structures along the second direction may be connected to the second portion of one of the conductive lines.

In an implementation, forming the first conductive line group and the second conductive line group arranged along the first direction in each sub-region of the first region may include providing an initial material layer. The method may further include forming a first mask pattern on the initial material layer. The first mask pattern may include a plurality of strip patterns extending along the first direction and arranged along the third direction. The method may further include forming a sidewall structure on a sidewall of the first mask pattern and removing the first mask pattern. The sidewall structure may include a plurality of ring-shaped patterns arranged along the third direction. The method may further include removing a middle portion of the sidewall structure in the first direction to form a first mask pattern group and a second mask pattern group arranged along the first direction. The first mask pattern group and the second mask pattern group may include a plurality of U-shaped mask patterns arranged along the third direction. The method may further include etching the initial material layer with the first mask pattern group and the second mask pattern group as masks to form the first conductive line group and the second conductive line group in the initial material layer.

In an implementation, forming the bit line structure extending along the first direction in the second region may include forming at least one bit line group in the second region while forming the conductive lines in the first region. The bit line group may include a plurality of bit line structures extending along the first direction and arranged along the third direction. The third direction is perpendicular to the first direction.

### BRIEF DESCRIPTION OF THE DRAWINGS

FIG. 1 is a schematic arrangement diagram I of a first region and a second region provided by examples of the present disclosure.

FIG. 2 is a schematic diagram of a memory array provided by examples of the present disclosure.

FIG. 3a is a schematic structural diagram I of a conductive line and a contact structure provided by examples of the present disclosure.

FIG. 3b is a schematic structural diagram II of a conductive line and a contact structure provided by examples of the present disclosure.

FIG. 4 is a cross-sectional view of FIG. 3a along a line A-A′.

FIG. 5 is a schematic structural diagram of a bit line structure and a bit line lead-out structure provided by examples of the present disclosure.

FIG. 6 is a cross-sectional view of FIG. 5 along a line B-B′.

FIG. 7 is a schematic structural diagram I of a first capacitor structure provided by examples of the present disclosure.

FIG. 8 is a schematic structural diagram II of a first capacitor structure provided by examples of the present disclosure.

FIG. 9 is a schematic structural diagram I of a memory device provided by examples of the present disclosure.

FIG. 10 is a schematic structural diagram II of a memory device provided by examples of the present disclosure.

FIG. 11 is an equivalent circuit diagram I provided by examples of the present disclosure.

FIG. 12 is an equivalent circuit diagram II provided by examples of the present disclosure.

FIG. 13 is a schematic arrangement diagram II of a first region and a second region provided by examples of the present disclosure.

FIG. 14 is a schematic arrangement diagram III of a first region and a second region provided by examples of the present disclosure.

FIG. 15 is a schematic arrangement diagram IV of a first region and a second region provided by examples of the present disclosure.

FIG. 16 is a schematic arrangement diagram V of a first region and a second region provided by examples of the present disclosure.

FIG. 17 is a schematic arrangement diagram VI of a first region and a second region provided by examples of the present disclosure.

FIG. 18 is a schematic arrangement diagram VII of a first region and a second region provided by examples of the present disclosure.

FIG. 19 is a schematic arrangement diagram I of a conductive line and a contact structure in a sub-region provided by examples of the present disclosure.

FIG. 20 is a cross-sectional view of FIG. 19 along a line C-C′.

FIG. 21 is a cross-sectional view of FIG. 19 along a line D-D′.

FIG. 22 is a schematic arrangement diagram II of a conductive line and a contact structure in a sub-region provided by examples of the present disclosure.

FIG. 23 is a schematic arrangement diagram of a bit line structure and a bit line lead-out structure in a memory bank provided by examples of the present disclosure.

FIG. 24 is a flow diagram of a manufacturing method of a memory device provided by examples of the present disclosure, and

FIGS. 25 to 47 are schematic structural diagrams of a manufacturing process of a memory device provided by examples of the present disclosure.

### DETAILED DESCRIPTION

Example implementations disclosed by the present disclosure will be described below in more details with reference to the drawings. Although the example implementations of the present disclosure are shown in the drawings, the present disclosure may be implemented in various forms and should not be limited by the specific implementations set forth herein. These implementations are provided for a more thorough understanding of the present disclosure, and to fully convey a scope disclosed by the present disclosure to those skilled in the art.

In the following description, numerous specific details are given in order to provide a more thorough understanding of the present disclosure. It is apparent to those skilled in the art that the present disclosure may be practiced without one or more of these details. In other examples, in order to avoid confusion with the present disclosure, some technical features well-known in the field are not described. That is, all the features of the actual examples are not described herein, and well-known functions and structures are not described in detail.

In the drawings, like reference numerals denote like elements throughout the specification.

Spatially relative terms, such as “beneath”, “below”, “lower”, “under”, “over”, “upper”, and the like, may be used herein for ease of description to describe the relationship between one element or feature and other elements or features as illustrated in the figures. The spatially relative terms are intended to further encompass different orientations of a device in use or operation in addition to the orientation depicted in the figures. For example, if the device in the drawings is turned over, then the elements or the features described as “below” or “under” or “beneath” other elements may be oriented “on” the other elements or features. Thus, the example terms, “below” and “beneath”, may include both upper and lower orientations. The device may be orientated otherwise (rotated by 90 degrees or in other orientations), and the spatially descriptive terms used herein are interpreted accordingly.

The terms used herein are only intended to describe the particular examples, and are not used as limitations of the present disclosure. As used herein, unless otherwise indicated expressly in the context, “a”, “an” and “the” in a singular form are also intended to include a plural form. Terms “consist of” and/or “include”, when used in this specification, indicate the presence of the described features, integers, steps, operations, elements and/or components, but do not preclude the presence or addition of one or more of other features, integers, steps, operations, elements, components, and/or groups. As used herein, a term “and/or” includes any and all combinations of related items listed.

A vertical channel transistor occupies a smaller area than a planar transistor, and thus can be used for improving an integration level of a memory device. Taking a dynamic random access memory (DRAM) as an example, a DRAM memory array may include memory cells arranged in an array, each of which may include a vertical channel transistor and a capacitor structure connected to the vertical channel transistor and extending along a vertical direction. In addition to a memory array, a memory device further includes a peripheral circuit coupled with the memory array and configured to control the memory array. In order to further improve the integration level of the memory device, a memory device in which a peripheral circuit and a memory array are stacked in a vertical direction has been proposed.

In some examples, the peripheral circuit also needs to be provided with a capacitor structure to serve as a drive capacitor, a decouple capacitor, and the like. Since the capacitor structure generally has a large volume, if the capacitor structure is disposed in the peripheral circuit, at least one of the area or the thickness of the peripheral circuit may be increased, which is adverse to the miniaturization of the memory device. In this regard, the present disclosure provides the following implementations.

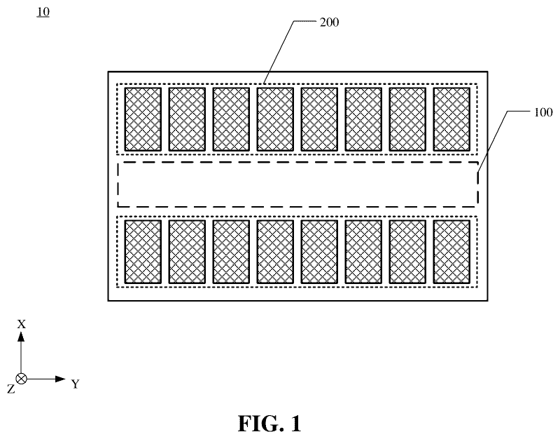

The present disclosure provides a memory device comprising a first semiconductor structure that includes a first region and a second region. FIG. 1 is a schematic diagram of a first semiconductor structure provided by examples of the present disclosure. As shown in FIG. 1, the first semiconductor structure 10 includes a first region 100 and a second region 200. Here, as an example, the second region 200 is symmetrically distributed on two sides of the first region 100 along a first direction.

In the examples of the present disclosure, a second direction is perpendicular to the first direction, and a third direction is perpendicular to both the first direction and the second direction. The first direction may be an X direction, the second direction may be a Z direction, and the third direction may be a Y direction.

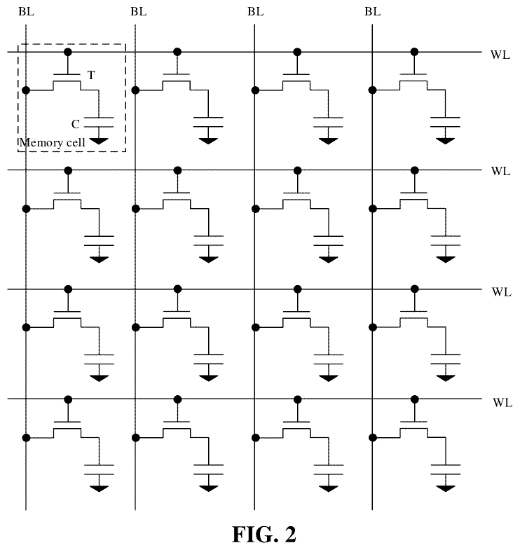

In some examples, the second region 200 includes a memory array composed of memory cells arranged in an array. FIG. 2 is a schematic diagram of a memory array provided by examples of the present disclosure. As shown in FIG. 2, the memory array includes a plurality of memory cells arranged in an array, a plurality of word lines WL, and a plurality of bit lines BL. Each memory cell includes one transistor T and one capacitor C, wherein a gate of the transistor T is connected to the word line WL; one of a source and a drain of the transistor T is connected to the bit line BL, and the other one of the source and the drain of the transistor T is connected to one electrode of the capacitor C; and the other electrode of the capacitor is grounded or connected to a fixed voltage (e.g., VCC/2). In the memory array, the capacitor C is configured to store data. In an example, a bit “1” or a bit “0” may be stored based on how much charge is stored in the capacitor C.

In the examples of the present disclosure, the first region 100 in the first semiconductor structure 10 may be a region where a first capacitor structure is disposed, and the second region 200 may be a region where a second capacitor structure is disposed, wherein the second capacitor structure may be the capacitor C configured to store data in the memory array shown in FIG. 2, and the first capacitor structure may be a capacitor coupled with a peripheral circuit and having other functions than data storage.

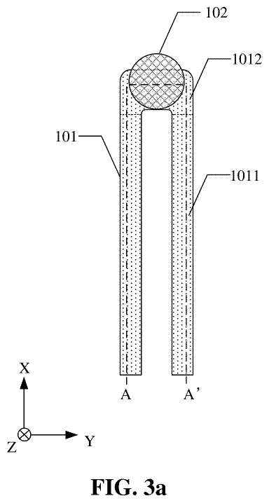

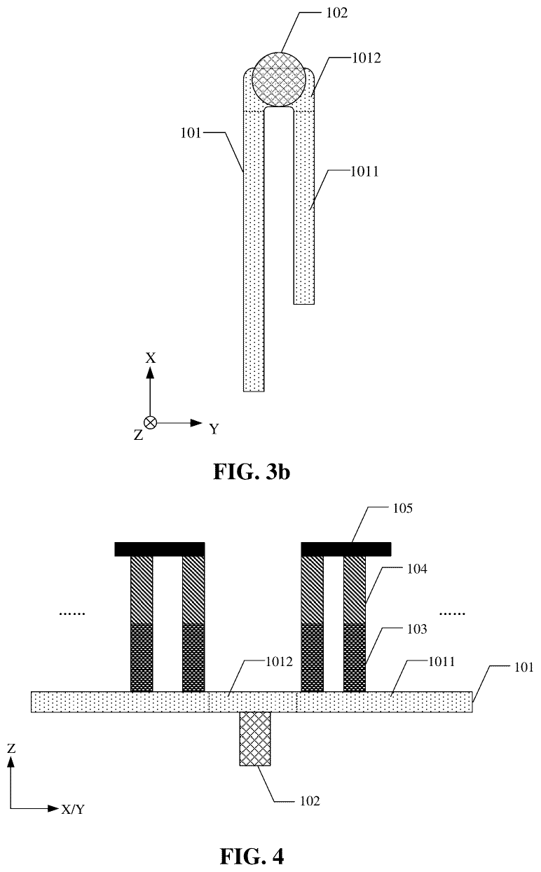

In some examples, the first region 100 includes a conductive line and a contact structure connected to the conductive line, and the second region 200 includes a bit line structure and a bit line lead-out structure connected to the bit line structure. In some examples, FIGS. 3a and 3b are schematic structural diagrams of the conductive line 101 and the contact structure 102 located in the first region 100, and FIG. 4 is a cross-sectional view of FIG. 3a along a line A-A′. Here, for ease of observing the shape of the conductive line 101, FIGS. 3a and 3b show a perspective view of the contact structure 102.

With reference to FIGS. 1, 3a and 4, the first region 100 includes: the conductive line 101 and the contact structure 102, wherein the conductive line 101 includes two first portions 1011 extending along the first direction and a second portion 1012 connecting the two first portions 1011; the second portion 1012 is connected to one of two opposite ends of the first portion 1011 along the first direction; the contact structure 102 extends along the second direction, and one of two opposite ends of the contact structure 102 along the second direction is connected to the second portion 1012.

In some examples, the first portions 1011 and the second portion 1012 of the conductive line 101 are integrally formed. The dotted lines in FIGS. 3a, 3b and 4 merely serve to mark the first portions 1011 and the second portion 1012, and are not boundaries present in an actual structure.

In some examples, with reference to FIG. 3a, the two first portions 1011 of the conductive line 101 may have the same size in the first direction.

In some examples, the conductive line 101 may include a metal silicide. Here, the metal silicide includes, but is not limited to, tungsten silicide, nickel silicide, cobalt silicide, and titanium silicide.

In some examples, the contact structure 102 may include a conductive material. Here, the conductive material may be one of a doped semiconductor material (e.g., doped silicon, doped germanium, etc.), a conductive metal nitride (e.g., titanium nitride, tantalum nitride, etc.), a metal material (e.g., tungsten, titanium, tantalum, etc.), and a metal semiconductor compound (e.g., tungsten silicide, cobalt silicide, titanium silicide, etc.).

In some examples, with reference to FIG. 4, the first region 100 further includes: a plurality of resistor structures 103. The resistor structure 103 extends along the second direction, and one of two opposite ends of the resistor structure 103 along the second direction is connected to the first portion 1011.

In some examples, the number of the resistor structures 103 connected to one of the two first portions 1011 of the conductive line 101 may be equal to the number of the resistor structures 103 connected to the other one of the two first portions 1011 of the conductive line 101.

In some other examples, with reference to FIG. 3b, the two first portions 1011 of the conductive line 101 may have different sizes in the first direction. In this case, the number of the resistor structures 103 connected to one of the two first portions 1011 of the conductive line 101 may be unequal to the number of the resistor structures 103 connected to the other one of the two first portions 1011 of the conductive line 101.

In some examples, in all the subsequent examples, the two first portions 1011 of the conductive line 101 have the same size in the first direction.

In some examples, FIG. 4 only shows two resistor structures 103 connected to each first portion 1011, but the present disclosure is not limited thereto. The number of the resistor structures 103 connected to each first portion 1011 is not limited by the examples of the present disclosure.

In the examples of the present disclosure, the resistor structure 103 has a pillar-shaped structure extending along the second direction. The cross-section shape of the resistor structure 103 in a direction perpendicular to the second direction includes, but is not limited to, a circle and a rectangle.

In some examples, the resistor structure 103 includes a doped semiconductor material. Here, the doped semiconductor material includes, but is not limited to, doped silicon, doped germanium, and doped silicon germanium.

In some examples, a doping concentration of the doped semiconductor material included in the resistor structure 103 is greater than 1×10¹⁵ cm⁻³.

In some examples, the doped semiconductor material includes an N-type material or a P-type material.

In some examples, the doped semiconductor material includes the N-type material, e.g., phosphorus (P) and arsenic (As) doped semiconductor materials.

In some other examples, the doped semiconductor material includes the P-type material, e.g., a boron (B) doped semiconductor material.

In some examples, with reference to FIG. 4, the first region 100 further includes: a plurality of first capacitor structures 104. The first capacitor structure 104 extends along the second direction, and the other one of two opposite ends of one of the resistor structures 103 along the second direction is connected to one of the first capacitor structures 104.

In the examples of the present disclosure, as an example, the contact structure 102 and the resistor structure 103 are located on the two sides of the conductive line 101 respectively. In some other examples, the contact structure 102 and the resistor structure 103 may be also located on the same side of the conductive line 101.

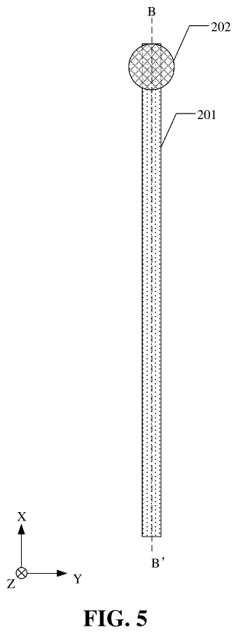

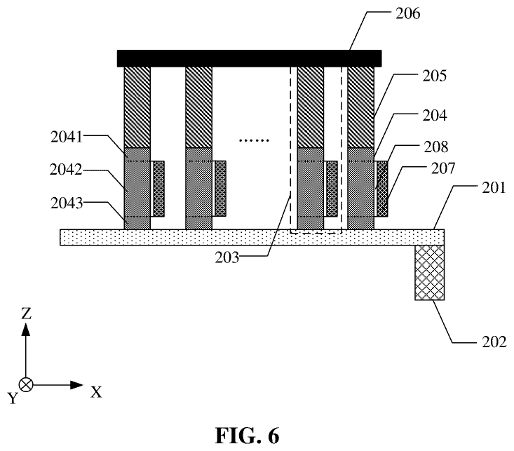

In some examples, FIG. 5 is a schematic structural diagram of a bit line structure 201 and a bit line lead-out structure 202 located in the second region 200 provided by examples of the present disclosure, and FIG. 6 is a cross-sectional view of FIG. 5 along a line B-B′. For ease of observing the shape of the bit line structure 201, FIG. 5 shows a perspective view of the bit line lead-out structure 202.

In some examples, with reference to FIGS. 1, 5 and 6, the second region 200 includes: the bit line structure 201 extending along the first direction; and the bit line lead-out structure 202 extending along the second direction, wherein one of two opposite ends of the bit line lead-out structure 202 along the second direction is connected to one of two opposite ends of the bit line structure 201 along the first direction.

In some examples, with reference to FIG. 6, the second region 200 includes a plurality of memory cells 203 connected to the bit line structure 201. Each memory cell 203 includes a transistor structure and a second capacitor structure 205. The transistor structure includes an active pillar 204, and the active pillar 204 and the second capacitor structure 205 both extend along the second direction. The active pillar 204 includes a first electrode structure 2041, a channel structure 2042 and a second electrode structure 2043 that are arranged along the second direction. One of the first electrode structure 2041 and the second electrode structure 2043 is connected to the bit line structure 201, and the other one of the first electrode structure 2041 and the second electrode structure 2043 is connected to the second capacitor structure 205. The second region 200 further includes a plurality of word line structures 207 extending along the third direction and a gate dielectric layer 208 located between the word line structures 207 and the channel structure 2042. The word line structure 207 may serve as a gate and form the transistor structure together with the active pillar 204.

Here, as an example, the word line structures 207 are located on a side of the channel structure 2042, but the present disclosure is not limited thereto. In some other examples, the word line structures may be located on two sides or three sides of the channel structure 2042 or surround the channel structure 2042.

In some examples, the resistor structure 103 in the first region 100 and the active pillar 204 in the second region 200 may include similar materials. In an example, the resistor structure 103 and the active pillar 204 may include a semiconductor material of the same type of doping, with the difference that in the active pillar 204, a doping concentration of the first electrode structure 2041 and the second electrode structure 2043 is greater than a doping concentration of the channel structure 2042, while a doping concentration of the resistor structure 103 may be the same at various heights in the second direction.

In some examples, the conductive line 101 in the first region 100 and the bit line structure 201 in the second region 200 may include the same material, and the contact structure 102 in the first region 100 and the bit line lead-out structure 202 in the second region 200 may include the same material.

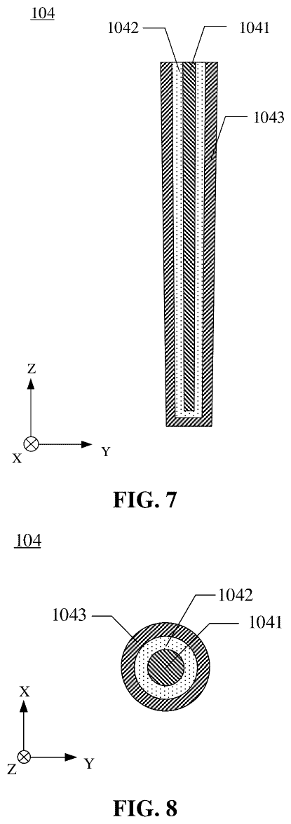

In some examples, the first capacitor structure 104 in the first region 100 and the second capacitor structure 205 in the second region 200 may have the same structure. Here, the structure of the first capacitor structure 104 is illustrated as an example. FIGS. 7 and 8 are schematic structural diagrams of the first capacitor structure 104 provided by the examples of the present disclosure. With reference to FIGS. 7 and 8, the first capacitor structure 104 has a pillar-shaped structure extending along the second direction. Along a radial direction (the X direction or the Y direction) of the first capacitor structure 104, the first capacitor structure 104 includes: a first electrode 1041, and a dielectric layer 1042 and a second electrode 1043 surrounding the first electrode 1041, wherein the dielectric layer 1042 is located between the first electrode 1041 and the second electrode 1043. The first electrode 1041 has a pillar-shaped structure, and the dielectric layer 1042 and the second electrode 1043 are film layer structures surrounding the first electrode 1041.

In some examples, the structure of the first capacitor structure 104 shown in FIGS. 7 and 8 is merely an example. The first capacitor structure 104 and the second capacitor structure 205 in the examples of the present disclosure may be also pillar-shaped capacitors having other structures.

In some examples, with reference to FIGS. 4 and 6, the first region 100 further includes a first upper electrode plate 105 connected to the first electrodes 1041 of a plurality of first capacitor structures 104. The first upper electrode plate 105 may be grounded or applied with other fixed voltages (e.g., VCC/2). The second region 200 further includes a second upper electrode plate 206 connected to the first electrodes of a plurality of second capacitor structures 205. The second upper electrode plate 206 may be grounded or applied with other fixed voltages (e.g., VCC/2). The first upper electrode plate 105 and the second upper electrode plate 206 may include the same conductive material.

In some examples, the memory device further includes a second semiconductor structure, and the first semiconductor structure and the second semiconductor structure are stacked in the second direction. The second semiconductor structure includes a peripheral circuit.

In some examples, FIG. 9 is a schematic structural diagram of the memory device. As shown in FIG. 9, the first semiconductor structure 10 and the second semiconductor structure 20 are stacked in the second direction. The first semiconductor structure 10 may include the first region 100 and the second region 200 that are arranged in juxtaposition along the direction (the X direction or the Y direction) perpendicular to the second direction, and a first interconnect layer 120. The second semiconductor structure 20 may include a peripheral circuit 210 and a second interconnect layer 220. The first interconnect layer 120 may include a first bonding pad 130, and the second interconnect layer 220 may include a second bonding pad 230. There may be no obvious boundary between the first bonding pad 130 and the second bonding pad 230.

In some examples, with reference to FIGS. 4, 6 and 9, one of the two opposite ends of the contact structure 102 in the first region 100 along the second direction not connected to the conductive line 101 may be further connected to a metal wiring in the first interconnect layer 120, and connected to the peripheral circuit 210 through the first bonding pad 130, the second bonding pad 230 and a metal wiring in the second interconnect layer 220. One of the two opposite ends of the bit line lead-out structure 202 in the second region 200 along the second direction not connected to the bit line structure 201 may be further connected to the metal wiring in the first interconnect layer 120, and connected to the peripheral circuit 210 through the first bonding pad 130, the second bonding pad 230 and the metal wiring in the second interconnect layer 220.

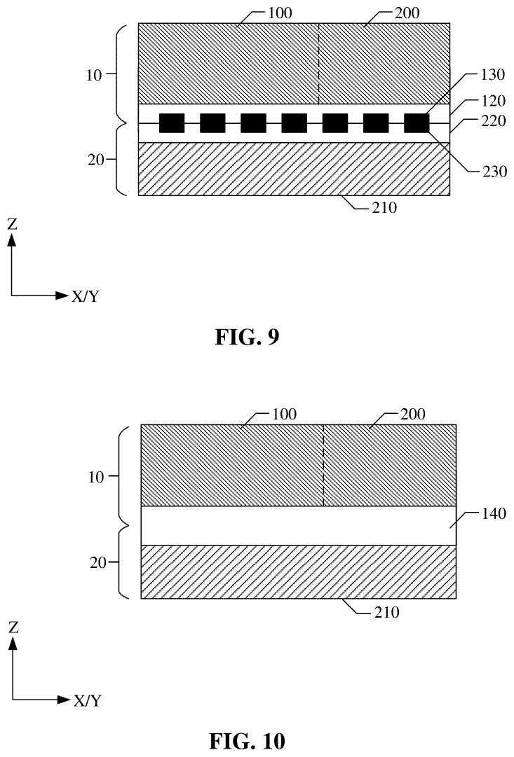

In some other examples, with reference to FIG. 10, the first semiconductor structure 10 and the second semiconductor structure 20 may not include a bonding pad. A wiring layer 140 may be included between the first region 100 and the peripheral circuit 210 and between the second region 200 and the peripheral circuit 210. One of the two ends of the contact structure 102 in the first region 100 along the second direction not connected to the conductive line 101 may be further connected to a metal wiring in the wiring layer 140, so as to be connected to the peripheral circuit 210 through the metal wiring.

In the examples of the present disclosure, the first region 100 and the second region 200 are both stacked with the peripheral circuit 210 in the second semiconductor structure 20 along the second direction. A circuit in the first region 100 comprising the first capacitor structure 104 may be coupled with the peripheral circuit 210 to serve as a capacitor having other functions than data storage. Thus, there is no need to dispose a capacitor structure with a large volume in the second semiconductor structure 20. More circuit elements can be disposed in the peripheral circuit 210 without altering the existing area and thickness, which facilitates improving the performance of the peripheral circuit 210. An increase in the area or thickness of the peripheral circuit 210 may be avoided, which facilitates the miniaturization of the memory device.

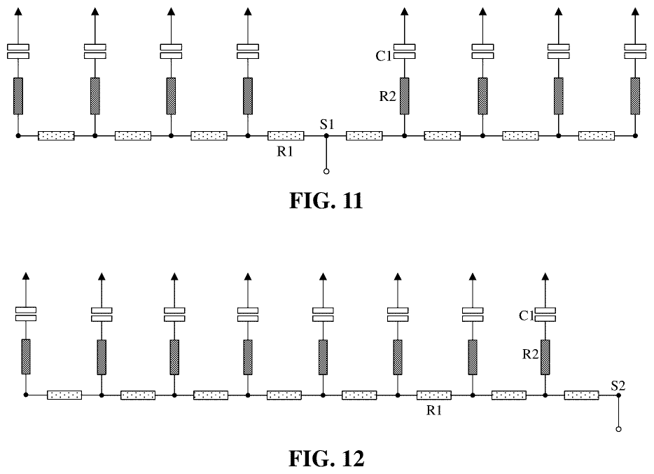

In some examples, FIG. 11 is an equivalent circuit diagram of a circuit structure consisting of one conductive line 101 in the first region 100 and a plurality of resistor structures 103 and a plurality of first capacitor structures 104 that are connected to the conductive line 101. The equivalent circuit includes a first resistor R1 having a resistance equivalent to the conductive line 101 of a unit length, a second resistor R2 having a resistance equivalent to the resistor structure 103, a capacitor C1 equivalent to the first capacitor structure 104, and a node S1 equivalent to a joint of the conductive line 101 and the contact structure 102. The node S1 is located in the middle of the circuit.

In some other examples, the conductive line in the first region 100 may have the same structure as the bit line structure 201 in the second region 200, and the contact structure is connected to one of the two opposite ends of the conductive line along the first direction. In this case, FIG. 12 is an equivalent circuit diagram of a circuit structure consisting of one conductive line and a plurality of resistor structures and a plurality of first capacitor structures that are connected to the conductive line. The equivalent circuit includes a first resistor R1, a second resistor R2 and a capacitor C1, and a node S2 equivalent to the joint of the conductive line and the contact structure. The node S2 is located at one end of the circuit.

With reference to FIGS. 11 and 12, when the number of resistor structures connected to one conductive line is the same, the resistance of the equivalent circuit shown in FIG. 11 is approximately equal to one half of the resistance of the equivalent circuit shown in FIG. 12. That is, the structure of the conductive line 101 provided by the examples of the present disclosure may reduce the resistance of the circuit coupled with the peripheral circuit 210 and comprising the first capacitor structure 104.

In some examples, the resistor structure 103 may include a heavily doped semiconductor material, i.e., a semiconductor material having a doping concentration of greater than 1×10¹⁸ cm-3. Thus, the resistance of first resistor R1 in the circuit equivalent to the resistor structure 103 can be reduced, thereby further reducing the total resistance of the circuit.

In some examples, the peripheral circuit 210 includes a CMOS circuit. The first capacitor structure 104 may serve as a drive capacitor of the CMOS circuit. In this case, reducing the total resistance of the circuit may reduce the RC (Resistance-Capacitance) delay of the drive capacitor and increase the response speed of the CMOS circuit, thus allowing for improved reliability of the memory device.

In some examples, the first region 100 and the second region 200 in the first semiconductor structure 10 may also have an alternative arrangement.

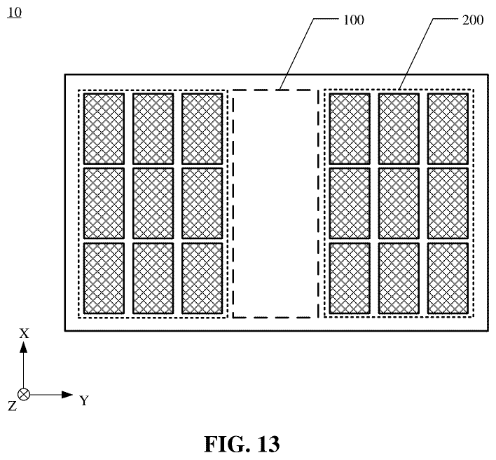

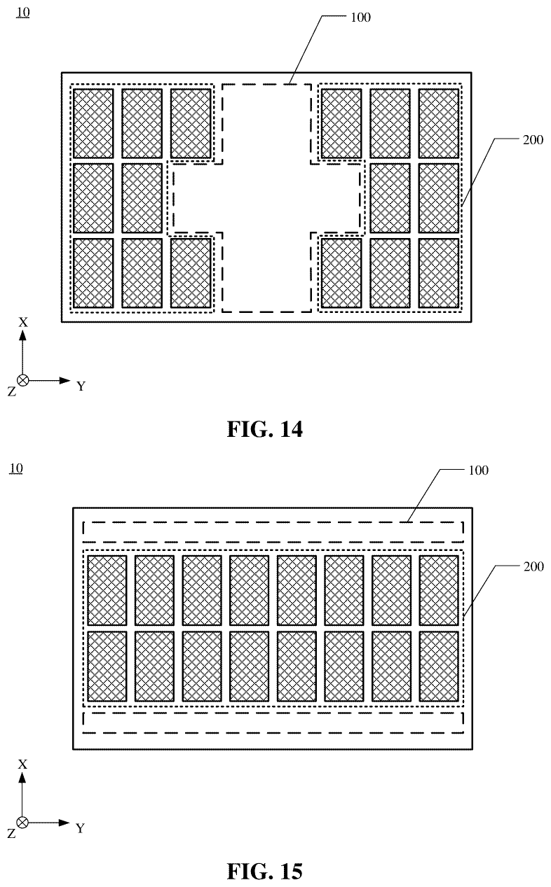

In some examples, with reference to FIGS. 13 and 14, two second regions 200 may be symmetrically distributed on the two sides of the first region 100 along the third direction.

In some examples, with reference to FIG. 15, two first regions 100 may be symmetrically distributed on two sides of the second region 200 along the first direction.

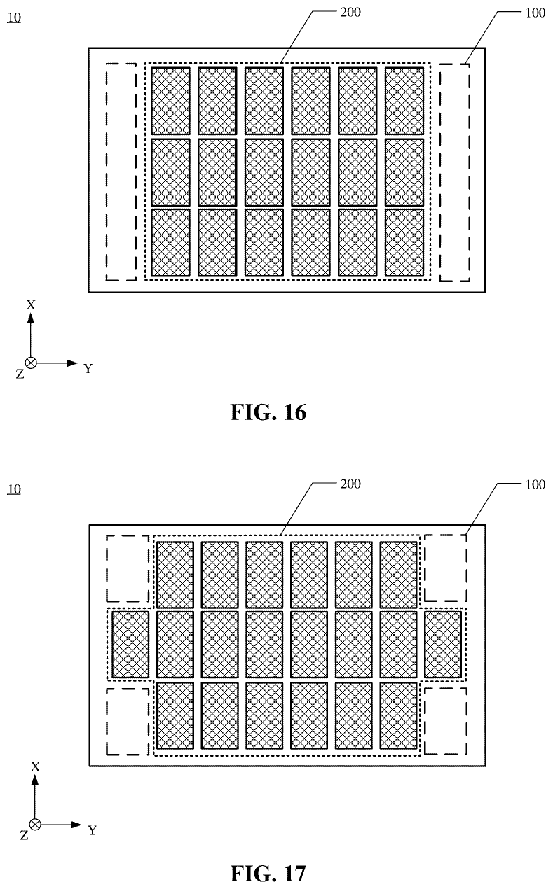

In some examples, with reference to FIG. 16, two first regions 100 may be symmetrically distributed on two sides of the second region 200 along the third direction.

In some examples, with reference to FIG. 17, the first semiconductor structure 10 may include four first regions 100, and every two first regions 100 may be symmetrically distributed on the two sides of the second region 200 along the third direction.

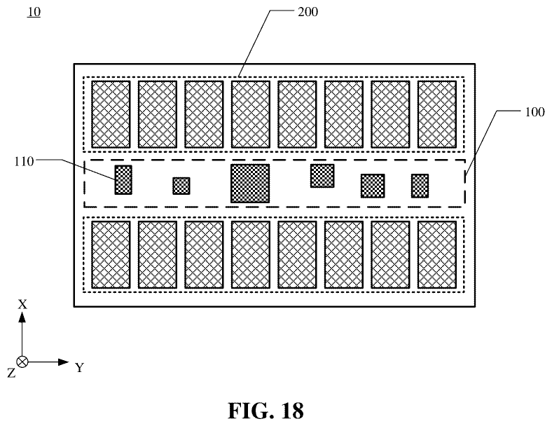

In some examples, with reference to FIG. 18, in the first semiconductor structure 10, the first region 100 includes at least one sub-region 110. Different sub-regions 110 may have different areas, and each sub-region 110 may include the conductive line, the resistor structure and the first capacitor structure. The first capacitor structures in different sub-regions 110 may have different functions.

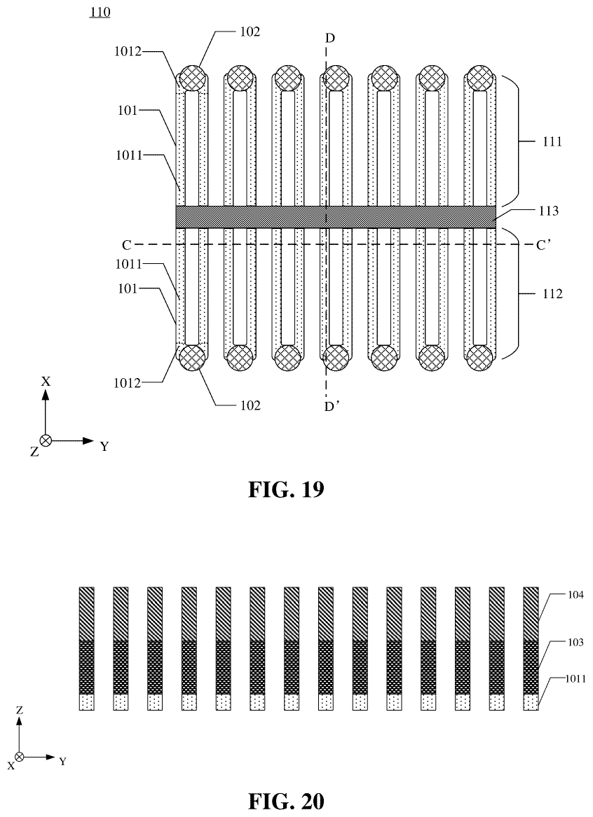

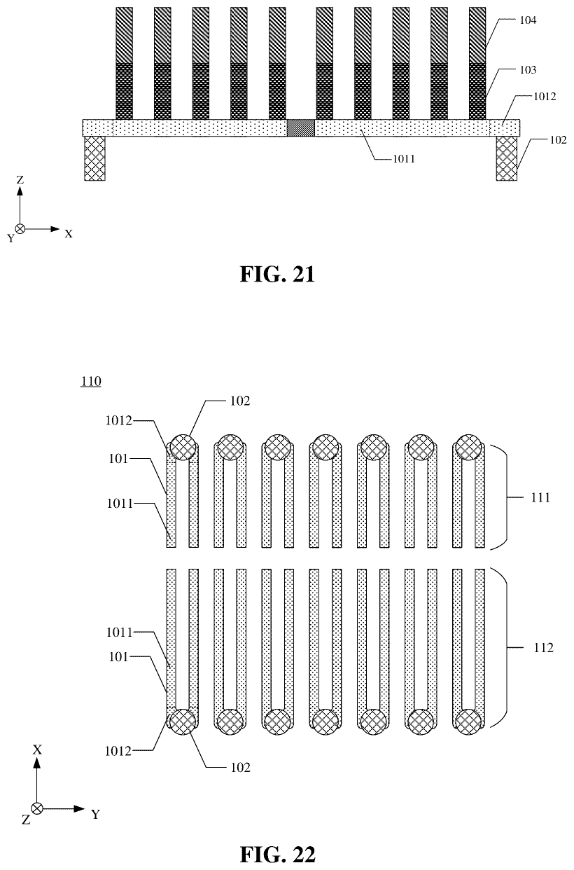

In some examples, FIG. 19 is a schematic arrangement diagram of the conductive line 101 and the contact structure 102 in one sub-region 110, FIG. 20 is a cross-sectional view of FIG. 19 along a line C-C′, and FIG. 21 is a cross-sectional view of FIG. 19 along a line D-D′.

In some examples, with reference to FIG. 19, each sub-region 110 includes: a first conductive line group 111 and a second conductive line group 112 that are arranged along the first direction. Each of the first conductive line group 111 and the second conductive line group 112 includes a plurality of conductive lines 101 arranged along the third direction. Each conductive line 101 includes two first portions 1011 extending along the first direction and the second portion 1012 connecting the two first portions 1011. The second portion 1012 is connected to one of two opposite ends of the first portion 1011 along the first direction. The second portion 1012 of the conductive line 101 in the first conductive line group 111 is located on one of two sides of the first portion 1011 along the first direction away from the second conductive line group 112. The second portion 1012 of the conductive line 101 in the second conductive line group 112 is located on one of the two sides of the first portion 1011 along the first direction away from the first conductive line group 111.

In some examples, with reference to FIGS. 19 and 21, each sub-region 110 includes a plurality of contact structures 102. The contact structures 102 extend along the second direction, and one of two opposite ends of one of the contact structures 102 along the second direction is connected to the second portion 1012 of one of the conductive lines 101.

In some examples, with reference to FIGS. 20 and 21, each sub-region 110 further includes a plurality of resistor structures 103. The resistor structures 103 extend along the second direction, and the plurality of resistor structures 103 are arranged in an array along the first direction and the third direction. One of two opposite ends of the resistor structure 103 along the second direction is connected to the first portion 1011 of the conductive line 101.

In some examples, the resistor structure 103 includes a doped semiconductor material.

In some examples, with reference to FIGS. 20 and 21, each sub-region 110 further includes a plurality of first capacitor structures 104. The first capacitor structure 104 extends along the second direction, and the other one of the two opposite ends of one of the resistor structures 103 along the second direction is connected to one of the first capacitor structures 104.

In some examples, with reference to FIG. 19, in each sub-region 110, the size of the conductive line 101 in the first conductive line group 111 in the first direction is the same as the size of the conductive line 101 in the second conductive line group 112 in the first direction; and the size of the conductive line 101 in the first conductive line group 111 in the third direction is the same as the size of the conductive line 101 in the second conductive line group 112 in the third direction.

In some examples, with reference to FIGS. 19 and 21, each sub-region 110 further includes an isolation structure 113 between the first conductive line group 111 and the second conductive line group 112. The conductive line 101 in the first conductive line group 111 and the conductive line 101 in the second conductive line group 112 are symmetrically distributed on two sides of the isolation structure 113 along the first direction.

In some other examples, with reference to FIG. 22, the size of the conductive line 101 in the first conductive line group 111 in the first direction may be also different from the size of the conductive line 101 in the second conductive line group 112 in the first direction. Here, as an example, the size of the conductive line 101 in the first conductive line group 111 in the first direction is smaller than the size of the conductive line 101 in the second conductive line group 112 in the first direction.

In the examples of the present disclosure, the first region 100 may include at least one sub-region 110, and each sub-region 110 may include the first conductive line group 111 and the second conductive line group 112. The conductive lines 101 in the first conductive line group 111 and the second conductive line group 112 may each have a U-shaped structure, i.e., include two first portions 1011 extending along the first direction and the second portion 1012 connecting the two first portions 1011. The contact structure 102 is connected to the second portion 1012 having a larger size in the third direction. Thus, there may be a large contact area between the contact structure 102 and the conductive line 101, which may reduce the contact resistance, and further reduce the total resistance of the circuit comprising the first capacitor structure 104.

In the examples of the present disclosure, one end of the contact structure 102 that is not connected to the conductive line 101 may be connected to a metal wiring, so as to connect the circuit comprising the first capacitor structure 104 to the peripheral circuit 210. The first capacitor structures 104 in different sub-regions 110 may have different functions, thereby increasing the functions of the peripheral circuit 210.

In the examples of the present disclosure, in the same sub-region 110, a plurality of first capacitor structures 104 connected to the same conductive line 101 are connected in parallel, and a plurality of first capacitor structures 104 connected to a plurality of conductive lines 101 may be also connected in parallel to the same metal wiring, thereby further increasing the capacitance of the circuit. When the first capacitor structure 104 serves as the drive capacitor of the CMOS circuit, the first capacitor structure 104 may have a higher driving capability, so that the response speed of the CMOS circuit can be increased.

In some examples, with reference to FIGS. 13 to 18, the second region 200 may further include a plurality of rectangular memory banks, and each memory bank may include one bit line group.

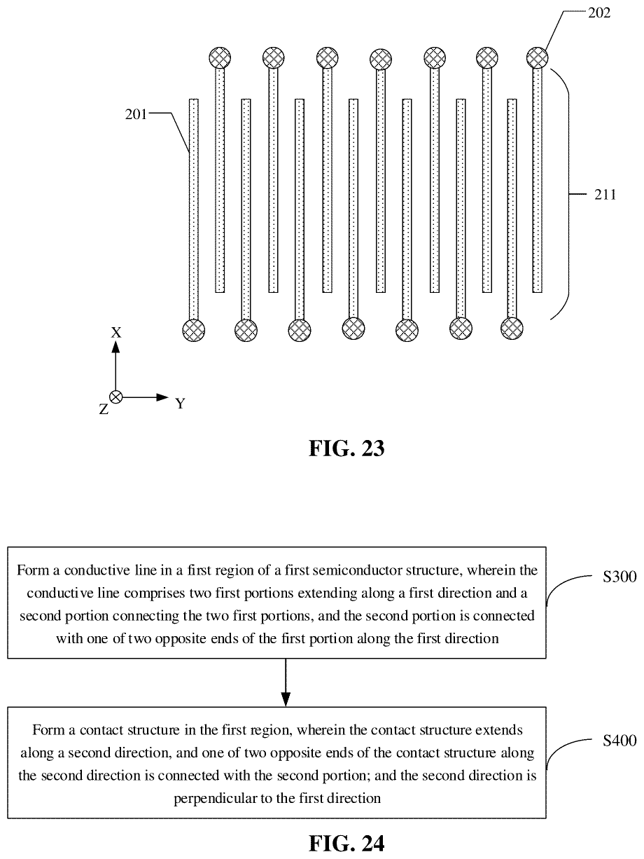

In some examples, FIG. 23 is a schematic arrangement diagram of bit line structures 201 and bit line lead-out structures 202 in one memory bank in the second region 200. As shown in FIG. 23, a bit line group 211 includes a plurality of bit line structures 201 extending along the first direction and arranged along the third direction. The second region 200 further includes a plurality of bit line lead-out structures 202 extending along the second direction. One of two opposite ends of one of the bit line lead-out structures 202 along the first direction is connected to one of two opposite ends of one of the bit line structures 201 along the first direction. The ends of two adjacent ones of the bit line structures 201 in the first direction are not aligned, and the bit line lead-out structure 202 connected to one of the bit line structures 201 is connected to one of the two opposite ends of the bit line structure 201 in the first direction that is away from the bit line lead-out structure 202 connected to the other one of the bit line structures 201. Thus, interference between the bit line lead-out structures 202 can be reduced. Here, the structure of the memory cells 203 arranged in an array and connected to the bit line structure 201 may refer to the description with respect to FIG. 6 in the previous examples, which will not be repeated here for brevity.

In the technical solutions provided by the present disclosure, the first region in the first semiconductor structure includes the conductive line and the contact structure connected to the conductive line. The conductive line includes two first portions extending along the first direction and a second portion connecting the two first portions. One end of the contact structure is connected to the second portion of the conductive line. The first region further includes a plurality of resistor structures connected to the first portion of the conductive line and first capacitor structures connected to the resistor structures. The contact structure is connected to the second portion of the conductive line, such that a circuit comprising the first capacitor structures is led out to the peripheral circuit. The resistance of the circuit can be reduced, the RC delay of the first capacitor structures can be reduced, and a response speed of the peripheral circuit can be increased, thereby improving reliability of the memory device. It may also avoid disposing a capacitor structure with a large volume in the peripheral circuit, which facilitates the miniaturization of the memory device.

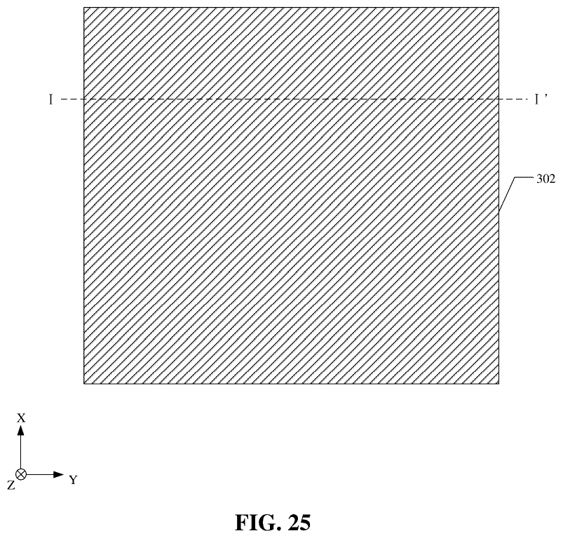

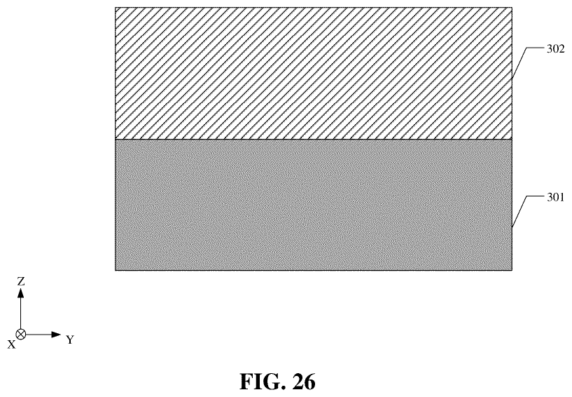

Based on a similar concept to the memory device described above, the present disclosure further provides a manufacturing method of a memory device. FIG. 24 is a flow diagram of a manufacturing method of a memory device provided by examples of the present disclosure. As shown in FIG. 24, the manufacturing method of the memory device includes:

S300: forming a conductive line in a first region of a first semiconductor structure, wherein the conductive line includes two first portions extending along a first direction and a second portion connecting the two first portions, and the second portion is connected to one of two opposite ends of the first portion along the first direction; and

S400: forming a contact structure in the first region, wherein the contact structure extends along a second direction, and one of two opposite ends of the contact structure along the second direction is connected to the second portion; and the second direction is perpendicular to the first direction.

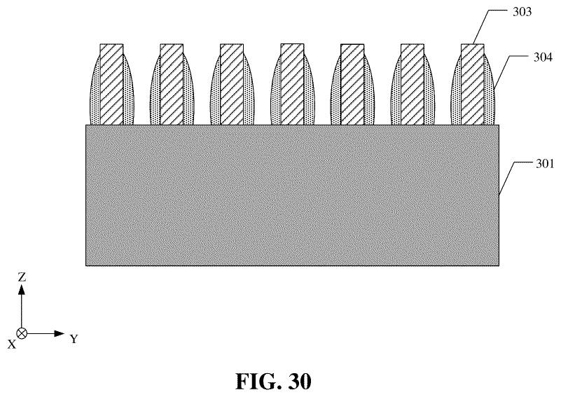

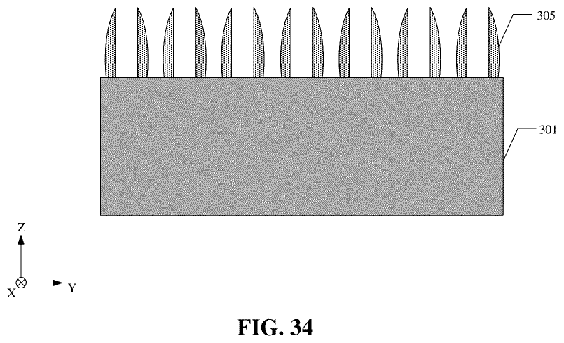

FIGS. 25 to 47 are schematic structural diagrams of a manufacturing process of a memory device. The manufacturing method of the memory device provided by the examples of the present disclosure will be described below with reference to FIGS. 24 to 47.

In some examples, referring back to FIG. 18, the manufacturing method of the memory device includes: forming the first region 100 and the second region 200 in the first semiconductor structure 10, wherein the first region 100 includes a plurality of sub-regions 110.

In the examples of the present disclosure, referring back to FIGS. 13 to 18, the first region 100 may be symmetrically distributed on two sides of the second region 200, or the second region 200 may be symmetrically distributed on two sides of the first region 100. Thus, the process non-uniformity caused by forming the first region 100 and the second region 200 simultaneously in the first semiconductor structure 10 can be reduced, and the reliability of the formed memory device can be improved.

In some examples, the execution of S300 may include: forming a first conductive line group and a second conductive line group arranged along the first direction in each sub-region 110 of the first region 100.

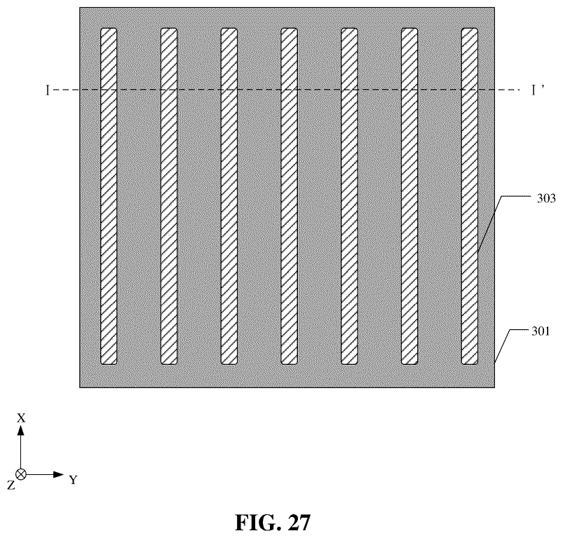

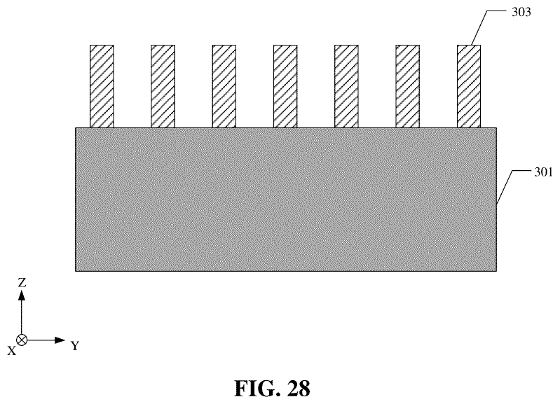

In some examples, with reference to FIGS. 25 to 28, FIG. 26 is a cross-sectional view of FIG. 25 along a line I-I′, and FIG. 28 is a cross-sectional view of FIG. 27 along a line I-I′. Forming the first conductive line group and the second conductive line group arranged along the first direction in each sub-region 110 of the first region 100 includes: providing an initial material layer 301, and forming a first mask pattern 303 on the initial material layer 301. In an example, a first mask layer 302 is formed on the initial material layer 301 by a deposition process, and the first mask pattern 303 is formed in the first mask layer 302 by a lithography process and an etching process. The first mask pattern 303 includes a plurality of strip patterns extending along the first direction and arranged along the third direction.

In the examples of the present disclosure, the deposition process includes, but is not limited to, chemical vapor deposition (CVD), low pressure chemical vapor deposition (LPCVD), plasma enhanced chemical vapor deposition (PECVD), physical vapor deposition (PVD) and atomic layer deposition (ALD). The etching process includes, but is not limited to, plasma etching (PE), sputtering etching (SE), ion beam etching (IBE) and reactive ion etching (RIE).

In some examples, the initial material layer 301 includes a semiconductor material. Here, the semiconductor material includes, but is not limited to, silicon, germanium, and silicon germanium.

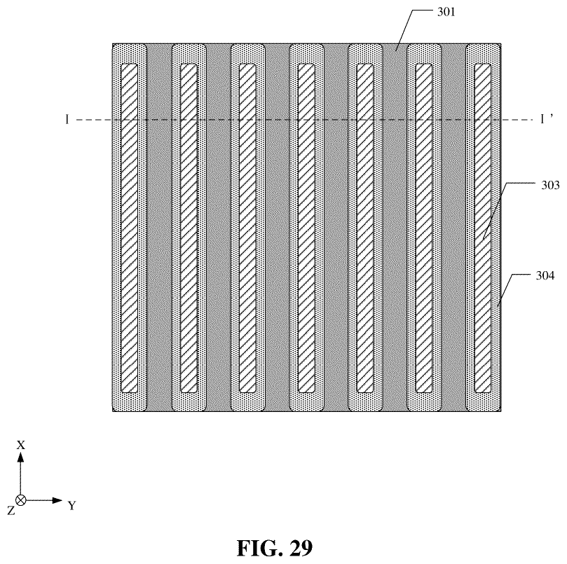

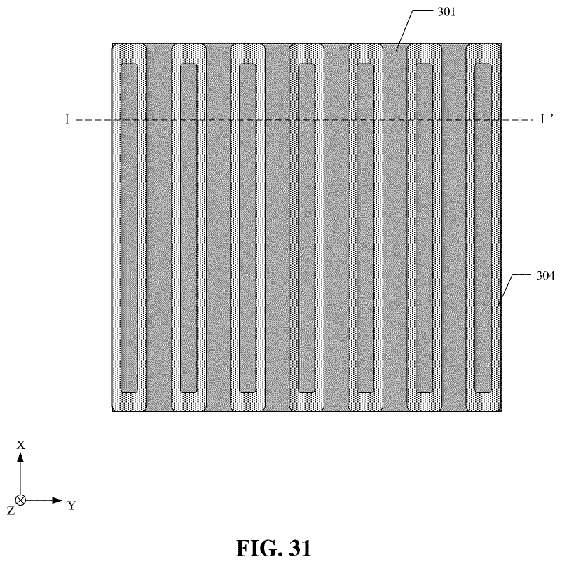

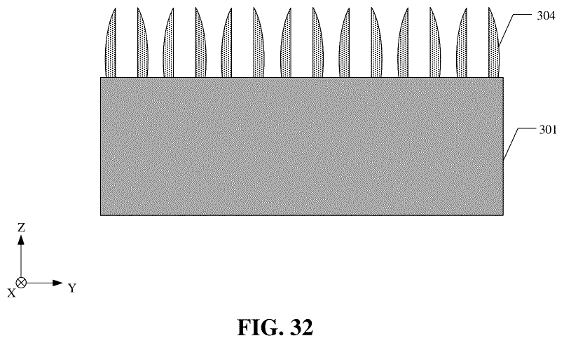

In some examples, with reference to FIGS. 29 to 32, FIG. 30 is a cross-sectional view of FIG. 29 along a line I-I′, and FIG. 32 is a cross-sectional view of FIG. 31 along a line I-I′. Forming the first conductive line group and the second conductive line group arranged along the first direction in each sub-region 110 of the first region 100 further includes: forming a sidewall structure 304 on a sidewall of the first mask pattern 303 and removing the first mask pattern 303, wherein the sidewall structure 304 includes a plurality of ring-shaped patterns arranged along the third direction.

In some examples, a dielectric material layer covering the first mask pattern 303 and the initial material layer 301 may be formed by an atomic layer deposition process. The dielectric material layer may include silicon oxide. Afterwards, a portion of the dielectric material layer that covers a top surface of the first mask pattern 303 and the initial material layer 301 is removed by a dry etching process to form the sidewall structure 304 covering the sidewall of the first mask pattern 303.

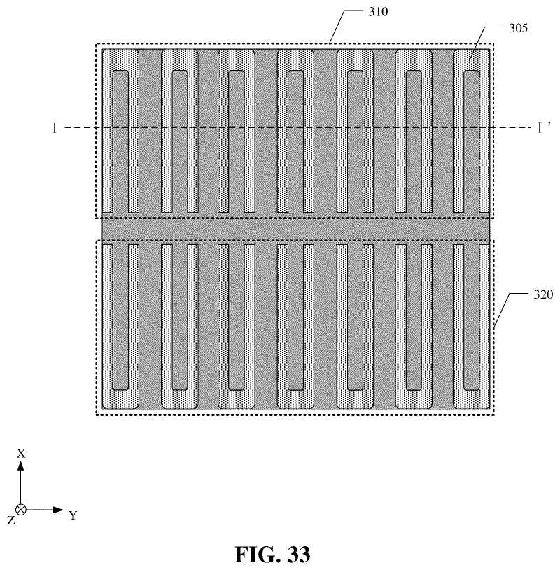

In some examples, with reference to FIGS. 31 to 34, FIG. 34 is a cross-sectional view of FIG. 33 along a line I-I′. Forming the first conductive line group and the second conductive line group arranged along the first direction in each sub-region 110 of the first region 100 further includes: removing a middle portion of the sidewall structure 304 in the first direction, to form a first mask pattern group 310 and a second mask pattern group 320 arranged along the first direction, wherein each of the first mask pattern group 310 and the second mask pattern group 320 includes a plurality of U-shaped mask patterns 305 arranged along the third direction.

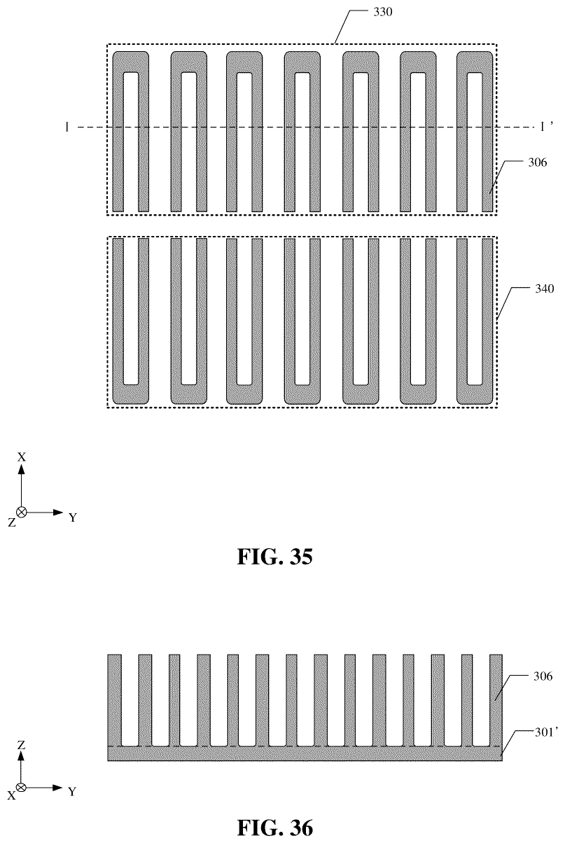

In some examples, with reference to FIGS. 33 to 36, FIG. 36 is a cross-sectional view of FIG. 35 along a line I-I′. Forming the first conductive line group and the second conductive line group arranged along the first direction in each sub-region 110 of the first region 100 further includes: etching the initial material layer 301 with the first mask pattern group 310 and the second mask pattern group 320 as masks, to form a first semiconductor pattern group 330 and a second semiconductor pattern group 340 in the initial material layer 301. Each of the first semiconductor pattern group 330 and the second semiconductor pattern group 340 on the remaining initial material layer 301′ includes a plurality of U-shaped semiconductor patterns 306 arranged along the third direction.

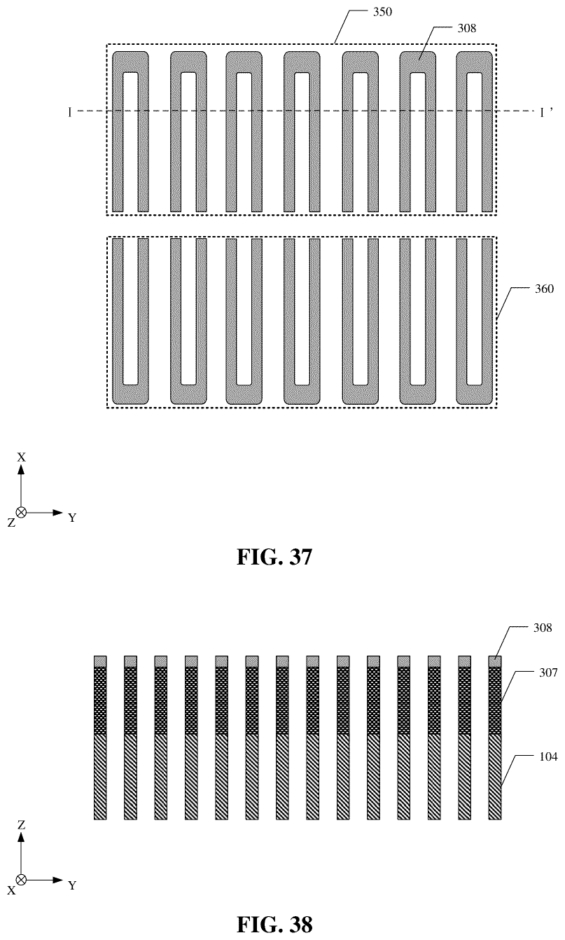

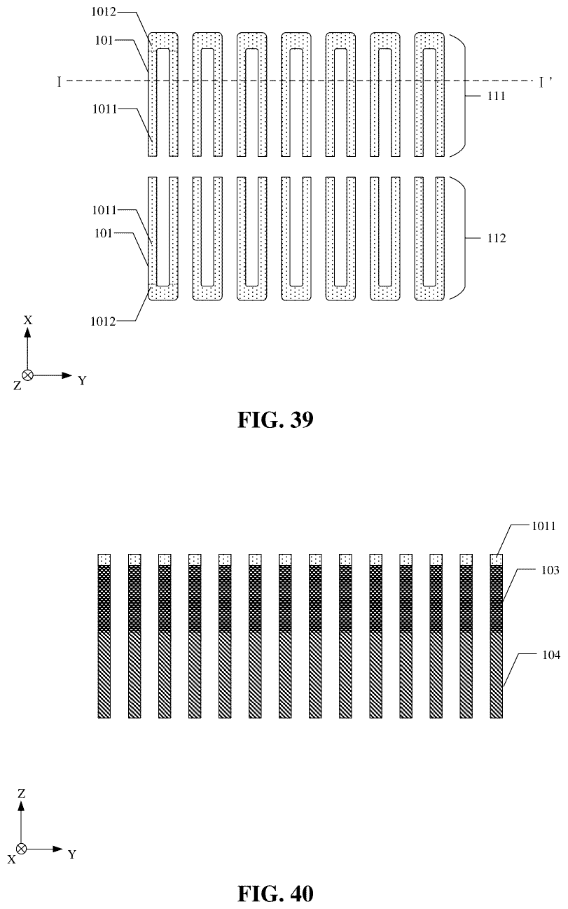

In some examples, with reference to FIGS. 35 to 40, FIG. 38 is a cross-sectional view of FIG. 37 along a line I-I′, and FIG. 40 is a cross-sectional view of FIG. 39 along a line I-I′. The manufacturing method of the memory device further includes: forming a plurality of resistor structures 103 and a plurality of first capacitor structures 104 in the first region 100, wherein the resistor structures 103 and the first capacitor structures 104 both extend along the second direction, and one of two opposite ends of one of the resistor structures 103 along the second direction is connected to one of the first capacitor structures 104. In an example, the U-shaped semiconductor pattern 306 may be etched along the second direction without being penetrated through, to form a plurality of semiconductor pillars 307 arranged in an array along the third direction and the first direction. The remaining U-shaped semiconductor pattern constitutes an initial conductive line 308. The semiconductor pillar 307 is doped to form the resistor structure 103. The first capacitor structure 104 is formed on a side of the resistor structure 103 away from the initial conductive line 308.

In some examples, with reference to FIGS. 35 to 40, forming the first conductive line group and the second conductive line group arranged along the first direction in each sub-region 110 of the first region 100 further includes: removing the remaining initial material layer 301′ from the other one of two opposite sides of the semiconductor pillar 307 along the second direction to expose the initial conductive line 308, and forming the conductive line 101 based on the initial conductive line 308, so as to form the first conductive line group 111 and the second conductive line group 112 arranged along the first direction. The conductive line 101 includes two first portions 1011 extending along the first direction and a second portion 1012 connecting the two first portion. The second portion 1012 is connected to one of two opposite ends of the first portion 1011 along the first direction, and one of two opposite ends of the resistor structure 103 along the second direction is connected to the first portion 1011.

In some examples, a material of the initial conductive line 308 includes silicon. A method of forming the conductive line 101 based on the initial conductive line 308 may include: forming a metal material layer covering the initial conductive line 308, and performing thermal treatment such that the material of the initial conductive line 308 is converted into a metal silicide to form the conductive line 101.

In some other examples, the method of forming the conductive line 101 based on the initial conductive line 308 may include: taking the initial conductive line 308 as a sacrificial pattern to remove the exposed initial conductive line 308, and filling a groove formed by removing the initial conductive line 308 with a conductive material to form the conductive line 101.

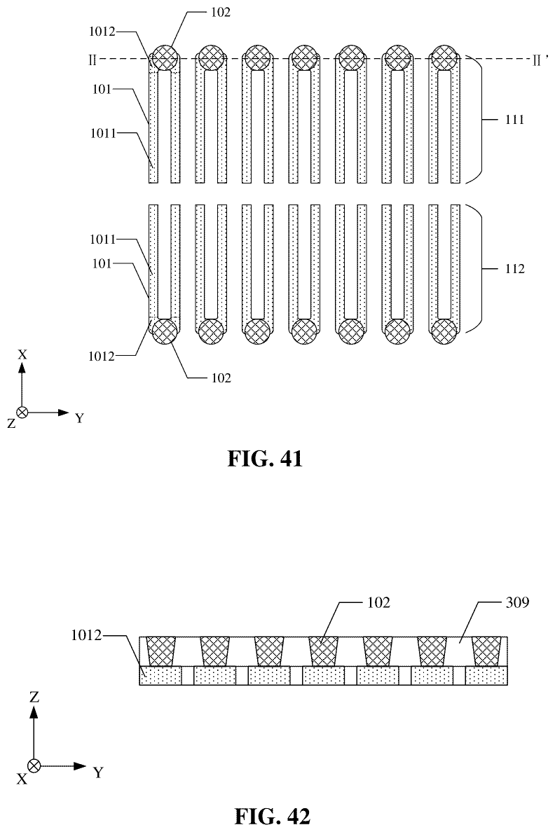

In some examples, with reference to FIGS. 41 and 42, FIG. 42 is a cross-sectional view of FIG. 41 along a line II-II′. The execution of S400 may include: forming a plurality of contact structures 102 in each sub-region 110 of the first region 100, wherein the contact structures 102 extend along the second direction, and one of two opposite ends of one of the contact structures 102 along the second direction is connected to the second portion 1012 of one of the conductive lines 101. In an example, the contact structure 102 may be formed from a side of the conductive line 101 away from the resistor structure 103 along the second direction, which includes forming an insulation layer 309 covering the conductive line 101, etching the insulation layer 309 along the second direction to form a trench exposing the second portion 1012 of the conductive line 101, and then filling the trench with a conductive material to form the contact structure 102. Here, as shown in FIG. 42, a size of an end of the formed contact structure 102 that is in contact with the second portion 1012 in the third direction may be smaller than a size of an end of the contact structure 102 that is away from the second portion 1012 in the third direction.

In the examples of the present disclosure, the contact structure 102 is formed to be connected to the second portion 1012 of the conductive line 101, while the resistor structure 103 is formed to be connected to the first portion 1011 of the conductive line 101. In the first conductive line group 111, the second portion 1012 of the conductive line 101 is located on a side of the first portion 1011 away from the second conductive line group 112; and in the second conductive line group 112, the second portion 1012 of the conductive line 101 is located on a side of the first portion 1011 away from the first conductive line group 111. Thus, the contact structure 102 may be formed at an edge that is away from the resistor structure 103 and the first capacitor structure 104, thereby avoiding a negative impact on other structures in the circuit during the process of forming the contact structure 102.

In the examples of the present disclosure, the size of the second portion 1012 in the third direction is greater than the size of the first portion 1011 in the third direction. Compared with forming the contact structure connected to the first portion 1011, when the insulation layer 309 is etched to form the trench, it may have a larger process margin, and the contact structure 102 may have a larger contact area with the conductive line 101. Therefore, the reliability of connection between the contact structure 102 and the conductive line 101 can be improved and the contact resistance can be reduced. Thus, the resistance of the circuit comprising the first capacitor structure 104 can be further reduced, and the RC delay of the first capacitor structure 104 can be reduced.

In some examples, the manufacturing method of the memory device further includes: forming a bit line structure extending along the first direction in the second region 200. In an example, at least one bit line group may be formed in the second region 200 while forming the conductive line 101 in the first region 100, wherein each bit line group includes a plurality of bit line structures extending along the first direction and arranged along the third direction.

In the examples of the present disclosure, a process of forming the bit line structure in the second region 200 is similar to the process of forming the conductive line 101 in the first region 100. The differences of the two forming processes will be briefly introduced below.

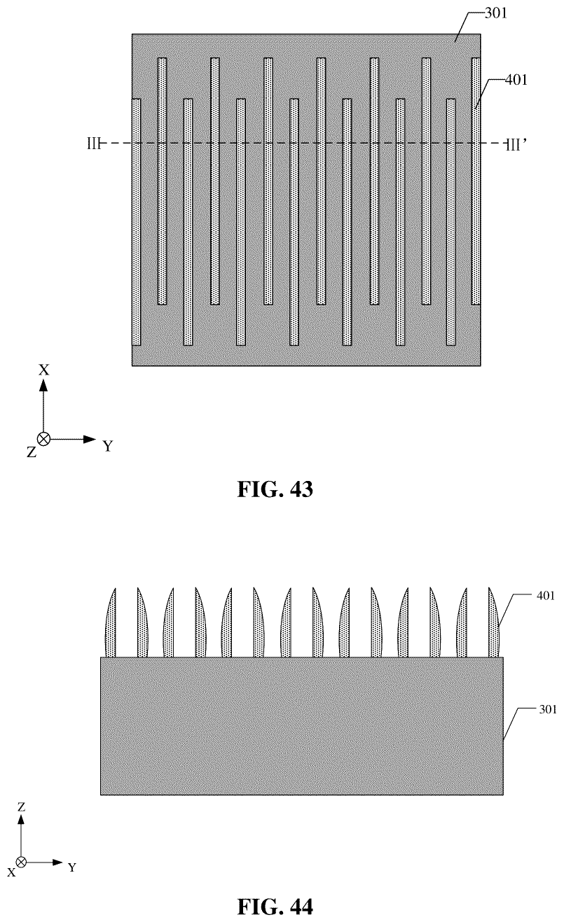

In some examples, with reference to FIGS. 31, 32, 43 and 44, FIG. 44 is a cross-sectional view of FIG. 43 along a line III-III′. After the sidewall structure 304 comprising the plurality of ring-shaped patterns is formed on the initial material layer 301, two opposite ends of the sidewall structure 304 in the first direction may be removed by etching, to form an initial semiconductor pattern 401 as shown in FIG. 43. The initial semiconductor pattern 401 includes strip patterns extending along the first direction and arranged along the third direction, and the ends of two adjacent ones of the initial semiconductor patterns 401 in the first direction are not aligned.

In some examples, with reference to FIGS. 43 to 46, FIG. 46 is a cross-sectional view of FIG. 45 along a line III-III′. The manufacturing method of the memory device further includes: forming a plurality of memory cells 203 arranged in an array in the second region 200, wherein the memory cell 203 includes an active pillar 204 and a second capacitor structure 205; and forming a bit line lead-out structure 202 extending along the second direction in the second region 200, wherein one of two opposite ends of the bit line lead-out structure 202 along the second direction is connected to one of two opposite ends of the bit line structure 201 along the first direction.

In some examples, a plurality of semiconductor pillars arranged in an array along the first direction and the third direction may be formed based on the initial semiconductor pattern 401, the remaining initial semiconductor pattern forms an initial bit line structure, and two opposite ends of the semiconductor pillar along the second direction are doped to form the active pillar 204. The active pillar 204 includes a first electrode structure 2041, a channel structure 2042 and a second electrode structure 2043 that are stacked along the second direction. Forming the active pillar 204 in the second region 200 and forming the resistor structure 103 in the first region 100 may be carried out simultaneously.

In some examples, the second capacitor structure 205 may be formed on each active pillar 204. Forming the second capacitor structure 205 in the second region 200 and forming the first capacitor structure 104 in the first region 100 may be carried out simultaneously.

In some examples, the remaining initial material layer may be further removed from the backside, and the bit line structure 201 may be formed based on the initial bit line structure. A plurality of bit line structures 201 arranged along the third direction constitute one bit line group 211. Forming the bit line structure 201 based on the initial bit line structure in the second region 200 and forming the conductive line 101 based on the initial conductive line 308 in the first region 100 may be carried out simultaneously.

In some examples, the bit line lead-out structure 202 may be formed on one of two opposite sides of the bit line structure 201 along the second direction away from the memory cell 203. Forming the bit line lead-out structure 202 in the second region 200 and forming the contact structure 102 in the first region 100 may be carried out simultaneously.

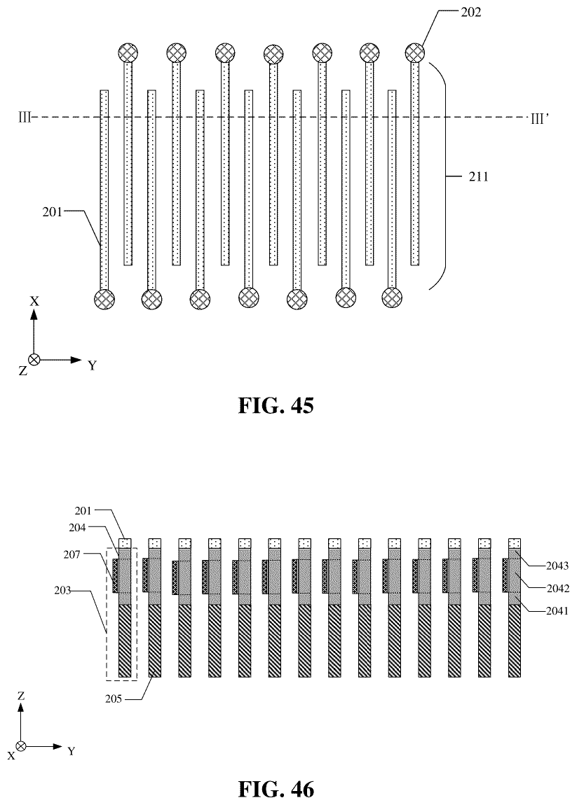

In some examples, with reference to FIG. 46, a word line structure 207 may be formed on at least one side of the channel structure 2042. While forming the word line structure 207 in the second region 200, a dummy conductive line having the same structure as the word line structure 207 may be also formed in the first region 100. In some other examples, the process of forming the dummy conductive line in the first region 100 may be omitted.

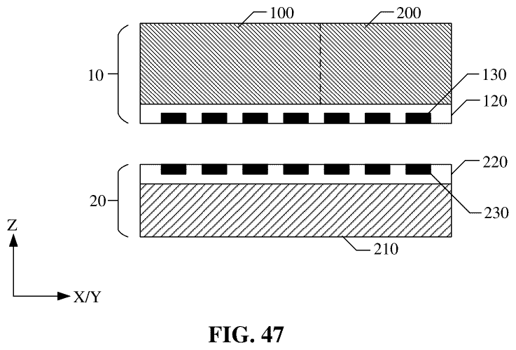

In some examples, with reference to FIGS. 47 and 9, the forming method of the memory device further includes: forming a first interconnect layer 120 comprising a first bonding pad 130 on the same side of the first region 100 and the second region 200; forming a peripheral circuit 210 in the second semiconductor structure 20 and forming a second interconnect layer 220 comprising a second bonding pad 230 on a side of the peripheral circuit 210; and bonding the first semiconductor structure 10 to the second semiconductor structure 20. After the first semiconductor structure 10 is bonded to the second semiconductor structure 20, the other one of the two opposite ends of the contact structure 102 along the second direction may be connected to the peripheral circuit 210 through a metal wiring in the first interconnect layer 120, the first bonding pad 130, the second bonding pad 230 and a metal wiring in the second interconnect layer 220. Here, a bonding process may be a hybrid bonding process.

In the examples of the present disclosure, both the first region 100 and the second region 200 are disposed in the first semiconductor structure 10, and the first region 100 and the second region 200 are arranged in juxtaposition in a direction perpendicular to the second direction. The structures in the first region 100 and the structures in the second region 200 may be formed simultaneously. For example, the conductive line 101 in the first region 100 and the bit line structure 201 in the second region 200 may be formed simultaneously; the resistor structure 103 in the first region 100 and the active pillar 204 in the second region 200 may be formed simultaneously; the first capacitor structure 104 in the first region 100 and the second capacitor structure 205 in the second region 200 may be formed simultaneously; and the contact structure 102 in the first region 100 and the bit line lead-out structure 202 in the second region 200 may be formed simultaneously. Thus, the forming process of the circuit structure comprising the first capacitor structure 104 in the first region 100 may be integrated with the forming process of the memory array comprising the second capacitor structure 205 in the second region 200, thereby saving the process cost and improving the production efficiency of the memory device. Moreover, forming the circuit comprising the first capacitor structure 104 simultaneously by using the forming process of the memory array facilitates forming a circuit with a high integration level in which a plurality of first capacitor structures 104 are connected in parallel. Thus, there is no need to add a capacitor structure with a large volume in the peripheral circuit 210, and it can avoid increasing the area or the thickness of the peripheral circuit 210, which facilitates the miniaturization of the memory device.

The features disclosed in several device examples provided by the present disclosure may be arbitrarily combined to obtain a new device example without conflict.

The methods disclosed in several method examples provided by the present disclosure can be arbitrarily combined to obtain a new method example without conflict.

The above descriptions are merely specific implementations of the present disclosure, and the protection scope of the present disclosure is not limited thereto. Any variation or replacement that may be readily figured out by those skilled in the art within the technical scope disclosed by the present disclosure shall fall within the protection scope of the present disclosure.

What is claimed is:

1. A memory device, comprising a first semiconductor structure that comprises a first region, wherein the first region comprises:
a conductive line comprising two first portions extending along a first direction and a second portion connecting the two first portions, wherein the second portion is connected to one of two opposite ends of the first portion along the first direction; and
a contact structure extending along a second direction, wherein one of two opposite ends of the contact structure along the second direction is connected to the second portion, and the second direction is perpendicular to the first direction.

2. The memory device of claim 1, wherein the first region further comprises:
a plurality of resistor structures extending along the second direction, wherein one of two opposite ends of at least one of the resistor structures along the second direction is connected to the first portion; and
a plurality of first capacitor structures extending along the second direction, wherein the other one of the two opposite ends of one of the resistor structures along the second direction is connected to one of the first capacitor structures.

3. The memory device of claim 2, wherein the resistor structures comprise a doped semiconductor material.

4. The memory device of claim 3, wherein a doping concentration of the doped semiconductor material is greater than 1×10¹⁵ cm⁻³.

5. The memory device of claim 2, wherein a number of the resistor structures connected to one of the two first portions of the conductive line is equal to a number of the resistor structures connected to the other one of the two first portions of the conductive line.

6. The memory device of claim 1, further comprising:
a second semiconductor structure, wherein the first semiconductor structure and the second semiconductor structure are stacked along the second direction; the first semiconductor structure comprises the first region and a second region that are arranged in juxtaposition along a direction perpendicular to the second direction; the second region comprises a plurality of memory cells arranged in an array; and the second semiconductor structure comprises a peripheral circuit, and the other one of the two opposite ends of the contact structure along the second direction is connected to the peripheral circuit.

7. The memory device of claim 6, wherein the second region further comprises:
a bit line structure extending along the first direction; and
a bit line lead-out structure extending along the second direction, wherein one of two opposite ends of the bit line lead-out structure along the second direction is connected to one of two opposite ends of the bit line structure along the first direction.

8. The memory device of claim 6, wherein the second region is symmetrically distributed on two sides of the first region along the first direction;
the second region is symmetrically distributed on two sides of the first region along a third direction that is perpendicular to both the first direction and the second direction;
the first region is symmetrically distributed on two sides of the second region along the first direction; or
the first region is symmetrically distributed on two sides of the second region along the third direction.

9. A memory device, comprising a first semiconductor structure that comprises a first region, wherein the first region comprises a sub-region comprising:
a first conductive line group and a second conductive line group arranged along a first direction, wherein at least one of the first conductive line group and the second conductive line group comprises a plurality of conductive lines arranged along a third direction; at least one of the conductive lines comprises two first portions extending along the first direction and a second portion connecting the two first portions; the second portion is connected to one of two opposite ends of the first portion along the first direction; the second portion of at least one of the conductive lines in the first conductive line group is located on one of two sides of the first portion along the first direction away from the second conductive line group; the second portion of at least one of the conductive lines in the second conductive line group is located on one of two sides of the first portion along the first direction away from the first conductive line group; and the third direction is perpendicular to the first direction;
a plurality of contact structures extending along a second direction,
wherein one of two opposite ends of one of the contact structures along the second direction is connected to the second portion of one of the conductive lines; and
the second direction is perpendicular to the first direction.

10. The memory device of claim 9, wherein the sub-region further comprises:
a plurality of resistor structures extending along the second direction and arranged in an array along the first direction and the third direction, wherein one of two opposite ends of at least one of the resistor structures along the second direction is connected to the first portion; and
a plurality of first capacitor structures extending along the second direction, wherein the other one of the two opposite ends of one of the resistor structures along the second direction is connected to one of the first capacitor structures.

11. The memory device of claim 10, wherein the resistor structures comprise a doped semiconductor material.

12. The memory device of claim 10, further comprising:
a second semiconductor structure, wherein the first semiconductor structure and the second semiconductor structure are stacked along the second direction; the first semiconductor structure comprises the first region and a second region that are arranged in juxtaposition along a direction perpendicular to the second direction; the second region comprises a plurality of memory cells arranged in an array; and the second semiconductor structure comprises a peripheral circuit, and the other one of the two opposite ends of the contact structure along the second direction is connected to the peripheral circuit.

13. The memory device of claim 10, wherein the sub-region further comprises:
an isolation structure located between the first conductive line group and the second conductive line group in the first direction and extending along the third direction, wherein the conductive lines in the first conductive line group and the conductive lines in the second conductive line group are symmetrically distributed on two sides of the isolation structure along the first direction.

14. The memory device of claim 12, wherein the second region further comprises:
a plurality of bit line structures extending along the first direction and arranged along the third direction; and
a plurality of bit line lead-out structures extending along the second direction, wherein one of two opposite ends of one of the bit line lead-out structures along the second direction is connected to one of two opposite ends of one of the bit line structures along the first direction.

15. A manufacturing method of a memory device, comprising:
forming a conductive line in a first region of a first semiconductor structure, wherein the conductive line comprises two first portions extending along a first direction and a second portion connecting the two first portions, and the second portion is connected to one of two opposite ends of the first portion along the first direction; and
forming a contact structure in the first region,
wherein the contact structure extends along a second direction, and one of two opposite ends of the contact structure along the second direction is connected to the second portion; and
the second direction is perpendicular to the first direction.

16. The manufacturing method of claim 15, further comprising:
forming a plurality of resistor structures in the first region, wherein the resistor structures extend along the second direction, and one of two opposite ends of at least one of the resistor structures along the second direction is connected to the first portion; and
forming a plurality of first capacitor structures in the first region, wherein the first capacitor structures extend along the second direction, and the other one of the two opposite ends of one of the resistor structures along the second direction is connected to one of the first capacitor structures.

17. The manufacturing method of claim 16, wherein forming the plurality of resistor structures comprises:
forming a plurality of semiconductor pillars extending along the second direction; and
doping the semiconductor pillars to form the plurality of resistor structures.

18. The manufacturing method of the memory device of claim 15, further comprising:
forming a plurality of memory cells arranged in an array in a second region of the first semiconductor structure, wherein the first region and the second region are arranged in juxtaposition along a direction perpendicular to the second direction;
forming a peripheral circuit in a second semiconductor structure; and
bonding the first semiconductor structure to the second semiconductor structure to form a bonding interface between the first semiconductor structure and the second semiconductor structure, wherein the other one of the two opposite ends of the contact structure along the second direction is connected to the peripheral circuit.

19. The manufacturing method of claim 18, further comprising:
forming a bit line structure extending along the first direction in the second region; and
forming a bit line lead-out structure extending along the second direction in the second region, wherein one of two opposite ends of the bit line lead-out structure along the second direction is connected to one of two opposite ends of the bit line structure along the first direction.

20. The manufacturing method of claim 15, wherein forming the conductive line in the first region and forming the contact structure in the first region comprise:
forming a first conductive line group and a second conductive line group arranged along the first direction in at least one sub-region of the first region, wherein at least one of the first conductive line group and the second conductive line group comprises a plurality of conductive lines arranged along a third direction; the second portion of at least one of the conductive lines in the first conductive line group is located on one of two sides of the first portion along the first direction away from the second conductive line group; the second portion of at least one of the conductive lines in the second conductive line group is located on one of two sides of the first portion along the first direction away from the first conductive line group; and the third direction is perpendicular to the first direction; and
forming a plurality of contact structures in the sub-region of the first region, wherein one of two opposite ends of one of the contact structures along the second direction is connected to the second portion of one of the conductive lines.
